(19) United States
(12) Patent Application Publication
(10) Pub. No.: US 2006/0198946 A1
(43) Pub. Date: Sep. 7, 2006

(54) Method and apparatus for fabricating self-emission device

(75) Inventor: Hiroki Tan, Yamagata (JP)

Correspondence Address: ARENT FOX PLLC, 1050 CONNECTICUT AVENUE, N.W., SUITE 400, WASHINGTON, DC, 20036, US

(73) Assignee: TOHOKU PIONEER CORPORATION

(21) Appl. No.: 11/366,571

(22) Filed: Mar. 3, 2006

(30) Foreign Application Priority Data
Mar. 4, 2005 (JP) 2005-60722

(51) Int. Cl. B05D 5/06; B05D 5/12

(52) U.S. Cl. 427/66

(57) ABSTRACT

A method and an apparatus for fabricating a self-emission device are provided, including forming a bottom electrode on a substrate directly or via another layer and forming a top electrode on a stack of layers overlying the bottom electrode, in which no deposition defect portion is formed even in the presence of a foreign matter or a bump or a dip on a deposited surface such as on the bottom electrode. The apparatus includes a deposition chamber, a substrate holder for holding a substrate in the deposition chamber, a pressure control gas inflow path for introducing a pressure control gas into the deposition chamber, and a material gas generation portion, provided in the deposition chamber separately from the pressure control gas inflow path, for generating a deposition material gas. The bottom or top electrode or at least one of the stack of layers is deposited under pressure with the pressure control gas introduced into the deposition chamber.

### BACKGROUND OF THE INVENTION

The present invention relates to a method and an apparatus for fabricating a self-emission device.

The present application claims priority from Japanese Application No. 2005-060722, the disclosure of which is incorporated herein by reference.

In general, self-emission devices have a fundamental arrangement with a bottom electrode formed on a substrate directly or via another layer and a top electrode formed on a stack of layers overlying the bottom electrode. As shown in FIG. 1, the device structure of an organic EL device or one of the self-emission devices is divided into two types: one is the passive drive type (FIG. 1(a)) and the other is the active drive type (FIG. 1(b)). In the device structure of the passive drive type, at least one bottom electrode 2 is formed directly on a substrate 1, then a stack of layers 3 including an organic EL functioning layer is deposited thereon, and at least one top electrode 4 is further formed thereon. In the device structure of the active drive type, another layer 6 such as flattening film is formed so as to cover at least one drive element 5 (such as a TFT element) formed on the substrate 1, the bottom electrode 2 is then formed which electrically communicates with the drive element 5 via the another layer 6, a stack of layers 3 including an organic EL functioning layer is deposited on the bottom electrode 2, and the top electrode 4 is further deposited thereon.

In general, to form an electrode or a stack of layers in such a self-emission device, employed is a vacuum deposition method such as the vacuum vapor deposition method or the sputtering method. In the vacuum deposition method, a substrate having a deposited surface formed thereon is held in a deposition chamber which is maintained under a vacuum atmosphere, and a deposition source is disposed so as to oppose the deposited surface, so that the deposited surface is exposed to a deposition flow emitted from the deposition source to thereby perform a deposition.

Japanese Patent Laid-Open Publication No. 2004-137583 describes a vacuum vapor deposition apparatus for depositing the organic EL functioning layer of an organic EL device. This vacuum deposition apparatus includes a vapor deposition flow control portion for controlling the direction of a vapor deposition flow directed from a heating portion to a vapor deposition target, thereby providing an improved efficiency of usage of a vapor deposition material.

In the aforementioned vacuum deposition method, depositions are performed typically in a vacuum atmosphere of the order of 10⁻³ to 10⁻⁶ Pa. The deposition flow employed at this time has a long mean free path (the average distance the gas molecule or atom of the deposition flow travels between collisions with other molecules or atoms), thus having a relatively high directivity. In patterning a stack of layers via a mask, this high directivity serves to prevent the deposition flow from being redirected and reaching an area shielded by the mask and thereby provide a good patterning, also serving to increase the amount of the deposition flow reaching the deposited surface and thereby improve the efficiency of usage of the deposition material. However, conversely, in the presence of a foreign matter or the like on the deposited surface, this high directivity disadvantageously causes a deposition defect portion to be formed.

This will be explained with reference to FIG. 1(c). In fabricating the aforementioned self-emission device, for example, the bottom electrode 2 may be formed on the substrate 1 or the another layer 6, and then one stacked layer 31 may be deposited thereon. In this case, in the presence of a foreign matter D such as a dust particle on the bottom electrode 2, the deposition flow having the aforementioned high directivity would not reach a portion shaded by the foreign matter D, resulting in a deposition defect portion d being formed on that portion. With such a deposition defect portion being left as it is, another stacked layer or a top electrode may be formed thereon, in the case of which a deficiency such as leakage or a short circuit may be caused due to the deposition defect portion, resulting in a display defect in the self-emission device.

To address this problem, the deposited surface could be improved in cleanliness to completely eliminate the foreign matter D such as dust particles from the deposited surface. However, such a severe requirement for cleanliness during manufacturing processes would be impractical in consideration of the manufacturing cost, and the complete elimination of the foreign matter would also be practically impossible. On the other hand, even in the absence of the foreign matter but in the presence of some bump or dip on the deposited surface, there is apprehension that a like deposition defect portion may be formed.

### SUMMARY OF THE INVENTION

The present invention was developed in view of the aforementioned problems. It is therefore an object of the present invention to provide a method and an apparatus for fabricating a self-emission device, including forming a bottom electrode on a substrate directly or via another layer and forming a top electrode on a stack of layers overlying the bottom electrode. The method and apparatus are aimed not to form a deposition defect portion even in the presence of a foreign matter or a bump or a dip on a deposited surface such as on the bottom electrode, thereby causing no display defect of the self-emission device, and improving the yield of the self-emission device to reduce its manufacturing costs.

To achieve such an object, the method and apparatus for fabricating a self-emission device according to the present invention includes at least the following aspects set forth in the following independent claims.

Namely, according to one of the aspects of the present invention, a method for fabricating a self-emission device is provided, including forming a bottom electrode on a substrate directly or via another layer and forming a top electrode on a stack of layers overlying the bottom electrode. The method comprises the step of, in a deposition process for depositing the bottom or top electrode or at least one of the stack of layers, performing a deposition using a deposition material gas generation portion provided in a deposition chamber, with the deposition chamber held under pressure.

Furthermore, according to another aspect of the present invention, a method for fabricating a self-emission device is provided, including forming a bottom electrode on a substrate directly or via another layer and forming a top electrode on a stack of layers overlying the bottom electrode. The method comprises the step of, in a deposition process for depositing the bottom or top electrode or at least one of the stack of layers, performing a deposition using a deposition material gas generation portion, provided in a deposition chamber separately from a path for introducing apressure control gas, under pressure with the pressure control gas introduced into the deposition chamber.

Furthermore, according to still another aspect of the present invention, an apparatus for fabricating a self-emission device is provided, including forming a bottom electrode on a substrate directly or via another layer and forming a top electrode on a stack of layers overlying the bottom electrode. The apparatus comprises: a deposition chamber; substrate holding means for holding, in the deposition chamber, a substrate on which the self-emission device is formed; a pressure control gas inflow path for introducing a pressure control gas into the deposition chamber; and a material gas generation portion, provided in the deposition chamber separately from the pressure control gas inflow path, for generating a deposition material gas. In this apparatus, the bottom or top electrode or at least one of the stack of layers is deposited under pressure with the pressure control gas introduced into the deposition chamber.

### BRIEF DESCRIPTION OF THE DRAWINGS

These and other objects and advantages of the present invention will become clear from the following description with reference to the accompanying drawings, wherein:

FIGS. 1(a), 1(b), and 1(c) are explanatory views showing a conventional technique;

FIG. 2 is an explanatory view of a method and an apparatus for fabricating self-emission device according to an embodiment of the present invention, showing the main configuration of the fabrication apparatus;

FIG. 3 is an explanatory view of a method and an apparatus for fabricating a self-emission device according to an embodiment of the present invention, showing another mode of the fabrication apparatus;

FIG. 4 is an explanatory view showing the operation of a method and an apparatus for fabricating a self-emission device according to an embodiment of the present invention; and

FIG. 5 is an explanatory view showing an exemplary system in which a fabrication apparatus according to an embodiment of the present invention is incorporated into a series of processes for fabricating a self-emission panel.

### DETAILED DESCRIPTION OF THE PREFERRED EMBODIMENTS

Now, the present invention will be explained below in accordance with the embodiments. A method for fabricating self-emission devices according to an embodiment of the present invention includes forming a bottom electrode on a substrate directly or via another layer and forming a top electrode on a stack of layers overlying the bottom electrode. The method is characterized by comprising the step of, in a deposition process for depositing the bottom or top electrode or at least one of the stack of layers, performing the deposition using a deposition material gas generation portion provided in a deposition chamber with the deposition chamber held under pressure. As used herein, the deposition chamber held under pressure can be realized, e.g., by introducing a pressure control gas into the deposition chamber.

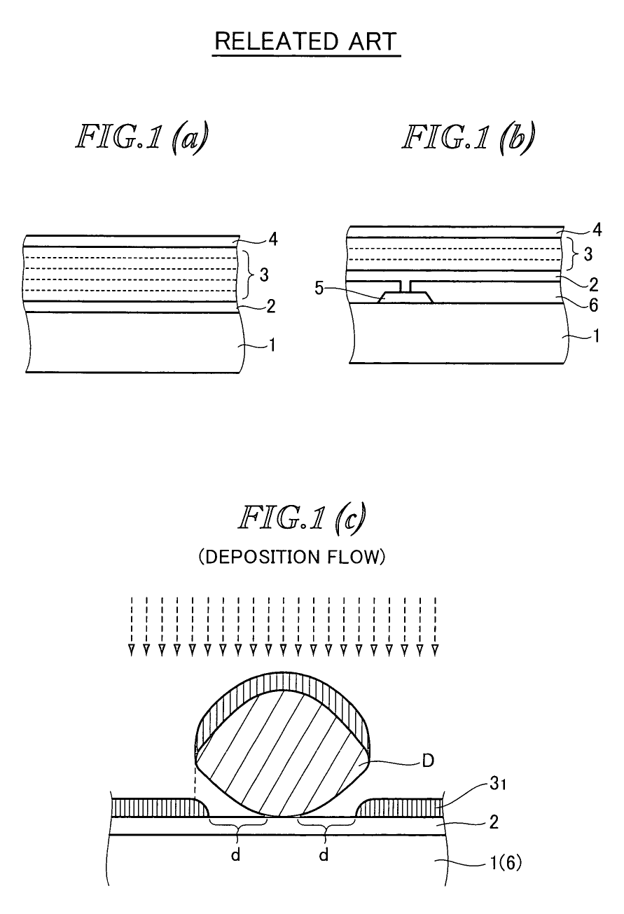

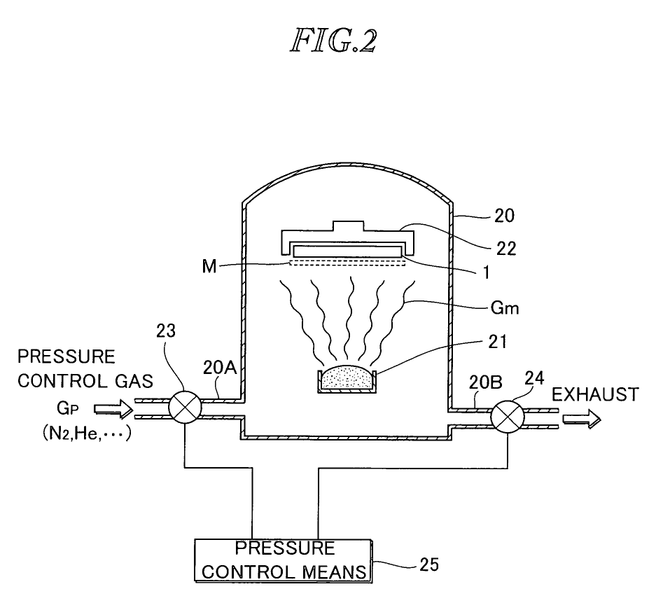

FIG. 2 is an explanatory view of a method and an apparatus for fabricating a self-emission device according to an embodiment of the present invention, showing the main configuration of the fabrication apparatus. As shown in FIGS. 1(a) and 1(b), this apparatus for fabricating a self-emission device is intended to form the bottom electrode 2 on the substrate 1 directly or via the another layer 6, and then form the top electrode 4 on the stack of layers 3 overlying the bottom electrode 2. The apparatus includes a deposition chamber 20; substrate holding means 22 for holding the substrate 1 in the deposition chamber 20; a pressure control gas inflow path 20A for introducing a pressure control gas Gp into the deposition chamber 20; and a material gas generation portion 21, provided in the deposition chamber 20 separately from the pressure control gas inflow path 20A, for generating a deposition material gas Gm. The bottom or top electrode 2, 4 or at least one of the stack of layers 3 is deposited under pressure with the pressure control gas Gp introduced into the deposition chamber 20.

The pressure control gas inflow path 20A is provided with inflow control means 23. The apparatus further includes pressure control means 25 for controlling the pressure of the deposition chamber 20 by controlling one of or both the inflow control means 23 and exhaust outflow control means 24 (provided in an exhaust path 20B) for controlling the exhaust from the deposition chamber 20.

Here, the pressure control gas Gp is a gas which does not react with the deposition material gas Gm, and may include an inert gas (such as N₂, He, or Ar). Or alternatively, an incombustible gas such as chlorofluorocarbons, a combustible gas such as methane, or a gas susceptible to combustion such as oxygen or N₂O may also be used depending on the type of the material gas Gm. The material gas generation portion 21 according to this embodiment is a deposition source located in the deposition chamber 20, and has a deposition material filled in a container made of, e.g., nickel, iron, cobalt-nickel alloy, stainless steel, graphite, or magnetic ceramics such as titanium nitride. The material gas generation portion 21 includes heating means, which works with resistance heating, high-frequency heating, laser heating, electron-beam heating or the like, for sublimation, or melting and evaporating, the deposition material to produce the material gas Gm. There may be disposed a deposition mask M, as required, between the material gas generation portion 21 and the deposited surface of the substrate 1.

The substrate holding means 22 holds the substrate 1 by vacuuming or otherwise securing it, and as required, may also include a mechanism for sustaining the substrate 1 in place, a mechanism for additionally providing a planar sliding movement or rotational movement, or a mechanism for additionally providing a vertical movement.

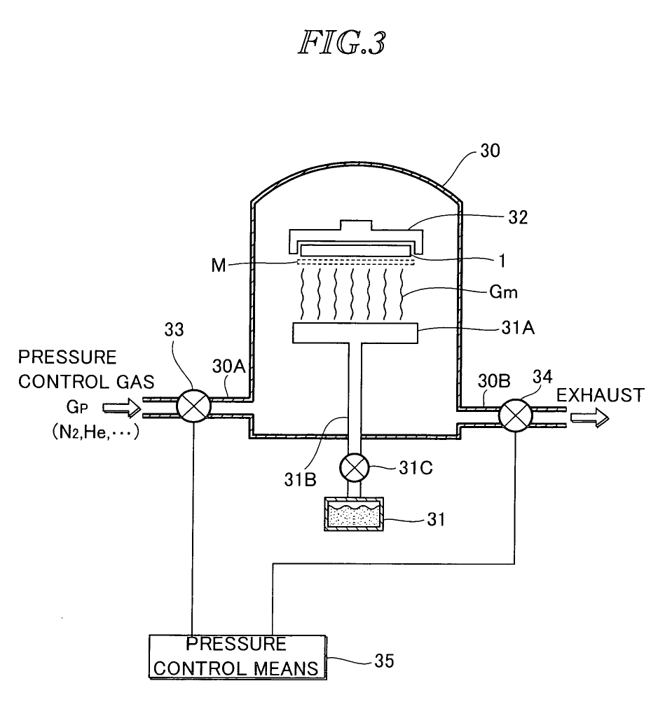

FIG. 3 is an explanatory view of a method and an apparatus for fabricating a self-emission device according to an embodiment of the present invention, showing another mode of the fabrication apparatus. Like the aforementioned embodiment, the apparatus according to this embodiment includes a deposition chamber 30; substrate holding means 32 for holding the substrate 1 in the deposition chamber 30; a pressure control gas inflow path 30A for introducing the pressure control gas Gp into the deposition chamber 30; and a material gas generation portion 31A, provided in the deposition chamber 30 separately from the pressure control gas inflow path 30A, for generating the deposition material gas Gm. The bottom electrode or at least one of the stack of layers is deposited under pressure with the pressure control gas Gp introduced into the deposition chamber 30. Furthermore, the pressure control gas inflow path 30A is provided with inflow control means 33. The apparatus also includes pressure control means 35 for controlling the pressure of the deposition chamber 30 by controlling one of or both the inflow control means 33 and exhaust outflow control means 34 (provided in an exhaust path 30B) for controlling the exhaust from the deposition chamber 30.

Further, in this embodiment, the material gas generation portion 31A disposed in the deposition chamber 30 is connected via a communication passageway 31B and a flow control valve 31C to a deposition source 31 disposed outside the deposition chamber 30. Like the aforementioned embodiment, the deposition mask M is also provided between the material gas generation portion 31A and the deposited surface of the substrate 1, as required.

A method for fabricating a self-emission device using such a fabrication apparatus is directed to the self-emission device (see FIGS. 1(a) and 1(b)) in which the bottom electrode 2 is formed on the substrate 1 directly or via the another layer 6, and then the top electrode 4 is formed on the stack of layers 3 overlying the bottom electrode 2. In a deposition process for depositing the bottom or top electrode 2, 4 or at least one of the aforementioned stack of layers 3, a deposition is performed using the deposition material gas generation portion 21 or 31A, which is provided in the deposition chamber 20 or 30 separately from the pressure control gas inflow path 20A or 30A, under pressure with the pressure control gas Gp introduced into the deposition chamber 20 or 30.

According to this arrangement, the deposition chamber 20 or 30 maintained under pressure will decrease the mean free path of the material gas Gm flow, thereby causing the gas flow to reduce or lose its directivity. The pressure at this time is a pressure at which the aforementioned mean free path can be reduced to a desired value and which is set typically to a less than atmospheric pressure of the order of 10⁻¹ to 10³ Pa, but may also be set to a more than atmospheric pressure (1.0133×10⁵ Pa), as required.

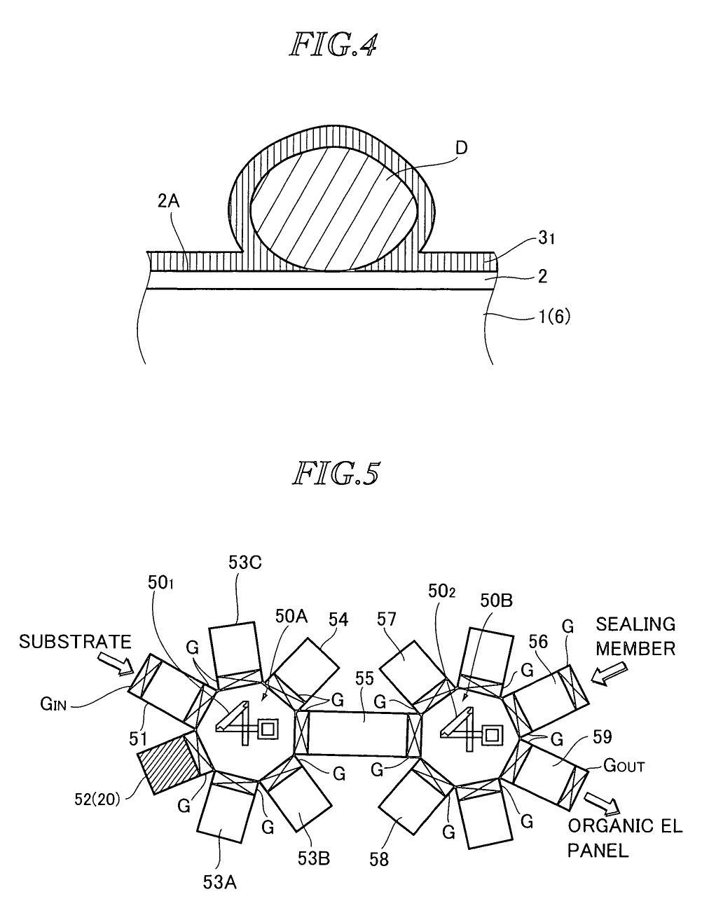

As shown in FIG. 4, even when a foreign matter D, a bump, or a dip is present on a deposited surface 2A thereby causing a portion shielded by the foreign matter D or the like to be formed on the deposited surface 2A, reducing the mean free path of the material gas Gm in this manner allows the material gas Gm to be redirected and reach the aforementioned shielded portion for deposition. Accordingly, the entire deposited surface is covered with the stacked layer 31 formed of the material gas Gm, thereby allowing no deposition defect portion to be formed on the deposited surface.

Furthermore, since the pressure control gas Gp to be introduced into the deposition chamber 20 or 30 to control the pressure is an inert gas such as N₂, He, or Ar, no reaction with the material gas Gm will occur resulting in no degradation in quality of the stacked layer 31. Furthermore, since the material gas generation portion 21 or 31A is provided in the deposition chamber 20 or 30 separately from the pressure control gas inflow path 20A or 30A, the material gas Gm flow would not be provided with an unnecessary directivity due to the pressure control gas Gp flowing therein.

The deposition process under such a pressure may be employed in depositing the bottom electrode 2, the top electrode 4, or at least one of the stack of layers 3, thereby making it possible to prevent the formation of the aforementioned deposition defect portion. In particular, as shown in FIG. 4, after the bottom electrode 2 was formed, the first stacked layer 3₁ is deposited under such a pressure to cover the entire surface of bottom electrode 2 with the stacked layer 3₁, thereby making it possible to eliminate a deficiency resulting from leakage or a short circuit.

Furthermore, in the deposition process under such a pressure, an unseparately colored layer is deposited on the bottom electrode 2 to cover the entire surface of the bottom electrode 2 with the unseparately colored layer, thereby effectively preventing leakage or a short circuit. In the case of the organic EL device, this deposition process may be effectively employed to deposit a hole injection layer, and an electron injection layer, which are not patterned such as for coloring on a per color basis.

Furthermore, the aforementioned pressure is set by the pressure control means 25 or 35 controlling one of or both the inflow control means 23 or 33 and the exhaust outflow control means 24 or 34 in order to control one of or both the inflow of the pressure control gas Gp and the exhaust outflow from the deposition chamber 20 or 30. To control the pressure, the pressure in the deposition chamber 20 or 30 can be controlled on the order of 10⁻³ to 10³ Pa, thereby controlling the mean free path of the material gas Gm in the range from a few meters to a few micrometers. The aforementioned pressure may be preferably controlled in the range of 10⁻¹ to 10³ in order for the material gas Gm to be effectively redirected and reach a portion shielded by a foreign matter or the like on the deposited surface.

Furthermore, in the deposition chamber 20 or 30 in which the deposition process is performed under such a pressure, the substrate 1 and the material gas generation portion 21 or 31A can be brought into close proximity to each other, thereby reducing the size of the deposition chamber 20 or 30. Additionally, the deposition chamber 20 or 30 does not require a high vacuum compatible performance, thereby making it possible to form the apparatus at relatively low costs.

FIG. 5 is an explanatory view showing an exemplary system in which the aforementioned fabrication apparatus according to an embodiment of the present invention is incorporated into a series of processes for fabricating a self-emission device. In general, by way of example, an organic EL panel is fabricated through a pre-process step, a deposition process, and a sealing process. The panel fabrication apparatus of FIG. 5 can provide an organic EL panel by performing the deposition process and the sealing process on a substrate that has been subjected to the pre-process step.

This apparatus is divided into two blocks: one is a deposition process block and the other is a sealing process block. In the deposition process block, a vacuum transfer chamber 50A equipped with a vacuum transfer robot 50₁ is surrounded by a substrate loading chamber 51, a pressure deposition chamber 52, and vacuum deposition chambers 53A, 53B, 53C, and 54, and a sealed gate G is provided between each chamber and the vacuum transfer chamber 50A. In the sealing process block, a transfer chamber 50B equipped with a transfer robot 50₂ is surrounded by a sealing member loading chamber 56, a sealing chamber 57, an emission characteristic inspection chamber 58, and an unloading chamber 59, and a sealed gate G is provided between each chamber and the transfer chamber 50B. Both the blocks communicate with each other through a transport chamber 55 having the sealed gate G at the ends thereof. The pressure deposition chamber 52 in this system is constituted by the aforementioned deposition chamber 20 (or 30).

Now, by way of example, a process for fabricating an organic EL panel using this fabrication process apparatus will be described below (see FIGS. 1(a) to 1(c), and 2 for the symbols other than those in FIG. 5). First, the substrate 1 on which the bottom electrode 2 such as of ITO or IZO or an insulating film such as of polyimide has been deposited and patterned in the pre-process step is loaded from an entrance gate GIN and temporarily stored in the substrate loading chamber 51. Then, after the substrate loading chamber 51 is pumped from atmospheric pressure into a vacuum environment, the substrate 1 is transported by the vacuum transfer robot 50₁ via the vacuum transfer chamber 50A into the pressure deposition chamber 52, where the first deposition process is to be performed.

In the pressure deposition chamber 52 (the deposition chamber 20), the substrate 1 is secured to the substrate holding means 22. Here, for example, the substrate holding means 22 may be preferably rotated so that the deposition material is deposited uniformly in thickness over the entire surface of the substrate 1. Then, the pressure control gas Gp of an inert gas such as N₂, He, or Ar is introduced through the pressure control gas inflow path 20A into the pressure deposition chamber 52 via the inflow control means 23, where the internal pressure is controlled by the pressure control means 25, e.g., to 100 Pa.

Then, the material gas Gm of a low molecular weight material such as CuPc or NPB is emitted from the material gas generation portion 21 so as to deposit the stacked layer 3₁ of a hole injection material on the bottom electrode 2.

The substrate 1 is then unloaded from the pressure deposition chamber 52 and transported to the next vacuum deposition chamber 53A. At this time, before the substrate is transported to the vacuum deposition chamber 52A, a processes for heating the substrate 1, a process for turning the environment back to an N₂ atmosphere, or a film thickness inspection process may be inserted (in the case of which a separate processing chamber is to be provided).

In the vacuum deposition chamber 52A, the deposition chamber is pumped, e.g., to a pressure of 1×10⁻⁴ Pa or less to vapor deposit a triphenyldiamine based compound (or so-called TPD) for deposition of a hole transport layer. Then, with the vacuum kept unchanged, the substrate 1 is moved to the next vacuum deposition chamber 52B, where a tris(8-hydroxyquinoline) aluminum complex (Alq₃) is vapor deposited to form an emission layer. Further, with the vacuum kept unchanged, the substrate 1 is moved to the next vacuum deposition chamber 53C, where LiF is vapor deposited to form an electron injection layer. Further, with the vacuum kept unchanged, the substrate 1 is moved to the next vacuum deposition chamber 54, where the top electrode 4 such as of Al, Ag, or Mg is deposited on the aforementioned organic EL functioning layer overlying the substrate 1.

The substrate 1 on which the organic EL device has been formed through the above deposition processes is passed via the transport chamber 55 to the transfer robot 50₂ in the sealing process block. Then, as required, an inspection such as on the emission characteristics is carried out in the inspection chamber 58, and the organic EL device is then sealed in the sealing chamber 57 before the substrate 1 is unloaded out of the system. In the sealing chamber 57, the sealing member loaded from the sealing member loading chamber 56 and the substrate 1 on which the organic EL device is formed are affixed via an adhesive layer in the inert gas atmosphere, thereby sealing the organic EL device in the sealed space between both the substrates. Thereafter, after the adhesive layer has been subjected to a predetermined heat hardening process, the organic EL panel is unloaded from an exit gate G_{OUT} of the unloading chamber 59.

In the deposition process according to this example, the deposition in the pressure deposition chamber 52 is performed to deposit the hole injection layer formed immediately on the bottom electrode 2, but without being limited thereto, may also be performed in combination of the deposition of another layer or the deposition of a plurality of layers. As described above, the deposition process in the pressure deposition chamber 52 allows the deposition material to be well redirected, and is thus useful, in forming an organic EL panel that emits multiple colors, for the deposition of a layer common to the multiple colors (an unseparately colored layer).

Now, a more detailed description, which will not limit the present invention in any manner, will be given to an organic EL panel for which the method and apparatus for fabricating a self-emission device according to an embodiment of the present invention is employed.

First, the organic EL device will be described. In general, the organic EL device is configured to have the organic EL functioning layer disposed between the anode (or a hole injection electrode) and the cathode (or an electron injection electrode). Application of a voltage to both the electrodes will cause the holes injected and transported from the anode to the organic EL functioning layer and the electrons injected and transported from the cathode to the organic EL functioning layer to recombine with each other in this layer (the emission layer) and thereby provide emission. By way of example, the following specific structures and materials may be applicable to the organic EL device in which the bottom electrode 2, the stack of layers 3 of the organic EL functioning layer, and the top electrode 4 are deposited on the substrate 1.

Preferably, the substrate 1 may be a transparent, flat, film-like substrate, and made of glass or plastics.

For the bottom or top electrode 2, 4, one is to be set as the cathode and the other as the anode. In this case, the anode may be preferably formed of a high work function material. That is, the anode is often made of a metal film such as chromium (Cr), molybdenum (Mo), nickel (Ni), or platinum (Pt); or alternatively a transparent conductive film of an oxide metal film such as ITO or IZO. On the other hand, the cathode may preferably be formed of a low work function material. In particular, the cathode can be made of a low work function metal such as an alkali metal (Li, Na, K, Rb, or Cs), an alkaline-earth metal (Be, Mg, Ca, Sr, or Ba), or a rare-earth metal, a compound thereof, or an alloy containing them. When both the bottom electrode 2 and the top electrode 4 are formed of a transparent material, a reflective film may also be provided on the electrode opposite to the emission side.

Furthermore, the lead electrodes extended from the bottom electrode 2 or the top electrode 4 out of the sealed space are provided to connect between the organic EL panel and drive means, such as an IC or a driver, for driving the organic EL panel. The lead electrodes are preferably made of a low resistance metal material such as Ag, Cr, or Al, or an alloy thereof.

In general, to form the bottom electrode 2 and the lead electrode, for example, a thin film for the bottom electrode 2 and the lead electrode is formed of ITO or IZO by vapor deposition or sputtering, and patterned by photolithography. As the bottom electrode 2 and the lead electrode (especially, a lead electrode required to be reduced in resistance), it is possible to employ a two-layer structure with a low resistance metal, such as Ag, an Ag alloy, Al, or Cr, deposited on the aforementioned underlying layer such as of ITO or IZO. Alternatively, a three-layer structure can also be employed in which a material, such as Cu, Cr, or Ta, having good resistance to oxidation is further deposited as a protective layer such as for Ag.

In general, when the bottom electrode 2 is the anode and the top electrode 4 is the cathode, employed as the organic EL functioning layer deposited between the bottom electrode 2 and the top electrode 4 is a stacked structure of the hole transport layer/the emission layer/the electron transport layer (when the bottom electrode 2 is the cathode and the top electrode 4 is the anode, employed is the stacked structure with the same layers but stacked in the reverse order). The emission layer, the hole transport layer, and the electron transport layer may be each formed not only in a single layer but also in multiple layers. Furthermore, either the hole transport layer or the electron transport layer may be eliminated or both of them may be eliminated leaving only the emission layer. As the organic EL functioning layer, it is also possible to insert an organic functioning layer such as a hole injection layer, an electron injection layer, a hole barrier layer, or an electron barrier layer depending on the application.

The material for the organic EL functioning layer can be selected, as appropriate, depending on the application of the organic EL device. By way of example, some of the materials are shown below but the invention is not limited thereto.

The hole transport layer is only required to have a high hole mobility and thus can be formed of any material selected from conventionally known compounds. Examples of the material for the hole transport layer include organic materials, e.g., porphyrin compounds such as copper phthalocyanine, aromatic triamines such as 4,4′-bis[N-(1-naphthyl)-N-phenylamino]-biphenyl (NPB), stilbene compounds such as 4-(di-p-tolylamino)-4′-[4-(di-p-tolylamino)styryl]stilbenzene, triazole derivatives, and styrylamine compounds. It is also possible to use a polymer dispersed material obtained by a low molecular weight hole transport organic material being dispersed in a polymer material such as polycarbonate. Preferably employed is a material whose glass transition temperature is higher than the temperature at which the sealing resin is hardened by heating, e.g., including 4,4′-bis[N-(1-naphthyl)-N-phenylamino]-biphenyl (NPB).

The emission layer may be formed of a well-known luminescent material, and specific examples include aromatic dimethylidyne compounds such as 4,4′-bis(2,2′-diphenylvinyl)-biphenyl (DPVBi); styryl benzene compounds such as 1,4-bis(2-methylstyryl)benzene; fluorescent organic compounds such as triazole derivatives including 3-(4-biphenyl)-4-phenyl-5-t-butylphenyl-1,2,4-triazole (TAZ), anthraquinone derivatives, and fluorenone derivatives; fluorescent organometal compounds such as (8-hydroxyquinolinato)aluminum complex (Alq₃); polymer materials such as poly p-phenylene vinylene (PPV) based, polyfluorene based, and polyvinyl carbazole (PVK) based materials; and organic materials such as platinum complexes and iridium complexes, capable of using phosphorescence from a triplet exciton for emission (Japanese Translation of PCT International Application No. 2001-520450). The emission layer may be formed only of the aforementioned luminescent material, or may also include a hole transport material, an electron transport material, an additive (such as a donor or an acceptor), or a luminescent dopant. These materials may also be dispersed in a polymer material or an inorganic material.

The electron transport layer is only required to serve to transfer the electrons injected from the cathode to the emission layer and thus can be formed of any material selected from conventionally known compounds. Examples of the material for the electron transport layer include organic materials such as nitro-substituted fluorenone derivatives and anthraquino-dimethane derivative, metal complexes such as 8-quinolinol derivatives, and metal phthalocyanine.

Except those layers that are deposited under pressure according to an embodiment of the present invention, the aforementioned hole transport layer, emission layer, and electron transport layer can be formed by a wet process, including a coating method such as the spin coating method and the dipping method or a printing method such as the ink-jet method and the screen printing method, or by a dry process, including the vapor deposition method and the laser transfer method, discussed later.

The organic EL device may form a single organic EL device or may also be provided with a desired patterned structure to form a plurality of pixels. In the latter case, the organic EL device may display in a single emission color or in two or more emission colors. In particular, to realize an organic EL panel for providing a plurality of emission colors, the following schemes are available. That is, a scheme (the separate coloring scheme) is available for forming emission functioning layers in two or more colors, including a scheme for forming three types of emission functioning layers corresponding to R, G, and B. Another scheme available is to combine an emission functioning layer of a single color, such as white or blue, with a color filter or a color conversion layer of a fluorescent material (the CF scheme or CCM scheme). Another scheme available is to irradiate the emission area of a single-color emission functioning layer with electromagnetic waves to implement multiple emissions (the photobleaching scheme). Another scheme available is the laser transfer scheme in which low molecular weight organic materials having different emission colors are pre-deposited on different films and then thermally transferred using a laser to one substrate.

Now, the aforementioned sealing member is not limited to a particular material but may be formed of any material so long as it ensures air tightness. However, for convenience in hardening an adhesive by heating, it is preferable to employ a material which is thermally less expanded or less degraded over time, including a glass material such as alkali glass or non-alkali glass, a metal material such as stainless steel or aluminum, or plastics. As the sealing member, it is possible to employ a glass sealing substrate having a sealing recessed portion (irrespective of one-step or two-step recessed portions) formed thereon by pressing, etching, or blasting. Alternatively, it is also possible to employ a glass flat plate to form a sealing space between the plate and the substrate using glass (or plastic) spacers, or a sealing member with a resin or the like filled in the sealed space between the sealing member and the substrate 1.

In place of these sealing members, a sealing film may also be used to seal the organic EL device. This sealing film can be formed by depositing a single layer film or a plurality of protective films, and may be made of either an organic or inorganic substance. Examples of the inorganic substance include nitrides such as SiN, AlN, and GaN, oxides such as SiO₂, Al₂O₃, Ta₂O₅, ZnO, and GeO, nitrogen oxides such as SiON, carbon nitrides such as SiCN, fluorometal compounds, and metal films. Examples of the organic substance include epoxy resins, acrylic resins, poly p-xylene, fluorine-based polymers such as perfluoro-olefin and perfluoro-ether, metal alkoxides such as CH₃OM and C₂H₅OM, polyimide precursors, and piperylene-based compounds. Depending on the design of the organic EL device, the stacked layer and material may be selected as appropriate.

The adhesive for adhering the sealing member to the substrate 1 maybe of a thermosetting type, a chemically cured (two-part mixing) type, or a light (ultraviolet) cured type, and made of acrylic resins, epoxy resins, polyesters, or polyolefins. In particular, the adhesive is preferably made of ultraviolet cured epoxy resin.

It is possible to dispose drying means (a desiccant) in the sealed space between the substrate 1 and the sealing member. The drying means may be formed of a physical desiccant such as zeolite, silica gel, carbon, and carbon nanotube; a chemical desiccant such as alkali metal oxide, metal halide, and chlorine peroxide; a desiccant made of an organic metal complex dissolved in a petroleum solvent such as toluene, xylene, and an aliphatic organic solvent; or a desiccant made of desiccant particles dispersed into a transparent binder such as polyethylene, polyisoprene, and polyvinyl cinnamate.

Now, an explanation will be given to an exemplary sealing process using a sealing member. An appropriate amount (about 0.1 to 0.5 wt %) of spacers (preferably glass or plastic spacers) having diameters from 1 to 300 μm is mixed with an adhesive of ultraviolet cured epoxy resin, and is then dispensed to a portion corresponding to the side wall of the sealing member on the substrate 1. Then, in an inert gas atmosphere such as an argon gas, the sealing member and the substrate 1 are affixed to each other via the adhesive. Subsequently, the adhesive is irradiated with an ultraviolet beam from the substrate 1 side (or from the sealing member side) to be thereby hardened. In this manner, the organic EL device is sealed with an inert gas such as an argon gas confined in the sealed space between the sealing member and the substrate 1.

In the case of the organic EL panel which employs an embodiment of the present invention, the organic EL device may transmit light according to the bottom emission scheme by which light is transmitted from the substrate 1 side or the top emission scheme by which light is transmitted from the side opposite to the substrate 1 (i.e., from the top electrode 4 side). Furthermore, as described above, the organic EL device may be driven according to the passive drive scheme or the active drive scheme.

### WORKING EXAMPLE

Now, taking a method for fabricating an organic EL device as an example, a working example of the present invention will be explained below.

By sputtering, ITO (Indium Tin Oxide) is deposited in a predetermined pattern on the surface of a transparent glass substrate, and the surface of the substrate is then abraded to thereby form the bottom electrode 2 in a predetermined thickness. For example, the surface of the bottom electrode 2 is abraded by polishing, lapping, or tape lapping to remove the dips and bumps on the surface (so that the maximum height (Rmax) is 50 angstroms or less, which is defined in “the definition and indication of surface roughness” (JIS-B0601-1994) specified in the Japan Industrial Standard (JIS)). Thereafter, the bottom electrode 2 is patterned by photolithography. Then, the substrate 1, on which the patterned bottom electrode 2 (the hole injection electrode) has been formed, is ultrasonically cleaned using neutral detergent, acetone, and ethanol. The substrate 1 is lifted out of the boiled ethanol and dried, and then the surface thereof is cleaned using UV/O₃.

Then, the substrate 1 (the substrate 1 that has been subjected to each process is hereinafter simply referred to as “the substrate”), on which the bottom electrode 2 has been formed as describe above, is loaded into the organic EL panel fabrication apparatus as shown in FIG. 5. The substrate is then fixed to a substrate holder (substrate holding means) in the pressure deposition chamber 52 (20), and the pressure deposition chamber 52 is controlled to a pressure of 100 Pa. Then, in the pressure deposition chamber 52, copper phthalocyanine (Cu-Pc) is vapor deposited to 50 nm on the bottom electrode 2 to form a hole injection layer.

Subsequently, using the robot arm (the vacuum transfer robot 50₁), the substrate is transferred from the pressure deposition chamber 52 to the vacuum deposition chamber 53A that has been pumped to a pressure of 1×10⁻⁴ Pa or less. Then, a hole transport layer is deposited to 50 nm in the vacuum deposition chamber 53A.

Then, while the vacuum is being kept unchanged, the robot arm (the vacuum transfer robot 50₁) moves the substrate to the next vacuum deposition chamber 53B, where a blue EL material of 4,4′-bis(2-carbazolevinylene)biphenyl (BCzVBi) added as a 1 wt % dopant to a host material of 4,4′-bis(2,2-diphenylvinyl)biphenyl (DPVBi) is deposited to 50 nm by dual-source vapor deposition.

Then, the substrate is moved to the vacuum deposition chamber 53C, where a red EL material of 4-dicyanomethylene-2-methyl-6-(p-dimethylaminostillene)-4H-pyr an (DCM) added as a 1 wt % dopant to a host material of tris(8-quinolinol) aluminum (Alq₃) is deposited to 50 nm by dual-source vapor deposition. Additionally, the substrate is moved to the next vacuum deposition chamber 54, where Alq₃ is further vapor deposited thereon to 20 nm as an electron transport layer, and aluminum (Al) to 150 nm as the cathode.

After the aforementioned deposition processes, the deposited organic EL device was checked on its emission condition in an emission inspection process. Then, the deposited organic EL device is loaded into the sealing chamber 57 in which the vacuum atmosphere has been changed to a N₂ inert gas atmosphere. On the other hand, a glass sealing substrate, whose surface has been provided with recessed portions by blasting with drying means of BaO disposed in the recessed portions, is simultaneously loaded into the sealing chamber 57. In the sealing chamber 57, an adhesive of ultraviolet cured epoxy resin mixed with an appropriate amount (about 0.1 to 0.5 wt %) of glass spacers having diameters from 1 to 300 μm is dispensed to a portion corresponding to the sealing substrate side wall on the glass sealing substrate. The glass sealing substrate coated with the adhesive and the substrate that has been subjected to the deposition processes are affixed to each other. Then, the adhesive is irradiated with an ultraviolet beam from the support substrate side (or from the sealing substrate side) to be thereby hardened, and thus a white organic EL device is completed.

As described above, an embodiment or a working example of the present invention provides the following features in fabricating a self-emission device, including forming a bottom electrode on a substrate directly or via another layer and forming a top electrode on a stack of layers overlying the bottom electrode. That is, even in the presence of a foreign matter or a bump or a dip on a deposited surface such as on the bottom electrode, it is possible to prevent the formation of a deposition defect portion that would otherwise lead to a display defect in the self-emission device. It is thus made possible to improve the yield of the self-emission device and thus reduce the manufacturing costs.

While there has been described what are at present considered to be preferred embodiments of the present invention, it will be understood that various modifications may be made thereto, and it is intended that the appended claims cover all such modifications as fall within the true spirit and scope of the invention.

1. A method for fabricating at least one self-emission device, including forming a bottom electrode on a substrate directly or via another layer and forming a top electrode on a stack of layers overlying the bottom electrode, the method comprising the step of:
in a deposition process for depositing the bottom or top electrode or at least one of the stack of layers, performing a deposition using a deposition material gas generation portion provided in a deposition chamber, with the deposition chamber held under pressure.

2. A method for fabricating at least one self-emission device, including forming a bottom electrode on a substrate directly or via another layer and forming a top electrode on a stack of layers overlying the bottom electrode, the method comprising the step of:
in a deposition process for depositing the bottom or top electrode or at least one of the stack of layers, performing a deposition using a deposition material gas generation portion, provided in a deposition chamber separately from a path for introducing a pressure control gas, under pressure with the pressure control gas introduced into the deposition chamber.

3. The method for fabricating at least one self-emission device according to claim 1, wherein
in the deposition process, a first layer in the stack of layers is deposited after the bottom electrode has been formed.

4. The method for fabricating at least one self-ernission device according to claim 1, wherein
in the deposition process, an unseparately colored layer is deposited on the bottom electrode.

5. The method for fabricating at least one self-emission device according to claim 2, wherein
the pressure is set by controlling an inflow of the pressure control gas and/or an exhaust outflow from the deposition chamber.

6. The method for fabricating at least one self-ernission device according to claim 1, wherein
the stack of layers is an organic EL functioning layer including an emission layer.

7. An apparatus for fabricating at least one self-emission device, including forming a bottom electrode on a substrate directly or via another layer and forming a top electrode on a stack of layers overlying the bottom electrode, the apparatus comprising:
a deposition chamber;
substrate holding means for holding, in the deposition chamber, a substrate on which the self-emission device is formed;
a pressure control gas inflow path for introducing a pressure control gas into the deposition chamber; and
a material gas generation portion, provided in the deposition chamber separately from the pressure control gas inflow path, for generating a deposition material gas, wherein
the bottom or top electrode or at least one of the stack of layers is deposited under pressure with the pressure control gas introduced into the deposition chamber.

8. The apparatus for fabricating at least one self-emission device according to claim 7, further comprising:
inflow control means provided in the pressure control gas inflow path; and
pressure control means for controlling the pressure of the deposition chamber by adjusting the inflow control means and/or means of controlling an exhaust outflow from the deposition chamber.

9. The method for fabricating at least one self-emission device according to claim 2, wherein
in the deposition process, a first layer in the stack of layers is deposited after the bottom electrode has been formed.

10. The method for fabricating at least one self-emission device according to claim 2, wherein
in the deposition process, an unseparately colored layer is deposited on the bottom electrode.

11. The method for fabricating at least one self-emission device according to claim 3, wherein
in the deposition process, an unseparately colored layer is deposited on the bottom electrode.

12. The method for fabricating at least one self-emission device according to claim 9, wherein
in the deposition process, an unseparately colored layer is deposited on the bottom electrode.

13. The method for fabricating at least one self-emission device according to claim 3, wherein
the pressure is set by controlling an inflow of the pressure control gas and/or an exhaust outflow from the deposition chamber.

14. The method for fabricating at least one self-emission device according to claim 9, wherein
the pressure is set by controlling an inflow of the pressure control gas and/or an exhaust outflow from the deposition chamber.

15. The method for fabricating at least one self-emission device according to claim 4, wherein
the pressure is set by controlling an inflow of the pressure control gas and/or an exhaust outflow from the deposition chamber.

16. The method for fabricating at least one self-emission device according to claim 11, wherein
the pressure is set by controlling an inflow of the pressure control gas and/or an exhaust outflow from the deposition chamber.

17. The method for fabricating at least one self-emission device according to claim 12, wherein
the pressure is set by controlling an inflow of the pressure control gas and/or an exhaust outflow from the deposition chamber.

18. The method for fabricating at least one self-emission device according to claim 2, wherein
the stack of layers is an organic EL functioning layer including an emission layer.

19. The method for fabricating at least one self-emission device according to claim 3, wherein
the stack of layers is an organic EL functioning layer including an emission layer.

20. The method for fabricating at least one self-emission device according to claim 9, wherein
the stack of layers is an organic EL functioning layer including an emission layer.

21. The method for fabricating at least one self-emission device according to claim 4, wherein
the stack of layers is an organic EL functioning layer including an emission layer.

22. The method for fabricating at least one self-emission device according to claim 11, wherein
the stack of layers is an organic EL functioning layer including an emission layer.

23. The method for fabricating at least one self-emission device according to claim 12, wherein
the stack of layers is an organic EL functioning layer including an emission layer.
